(19) United States
(12) Patent Application Publication
(10) Pub. No.: US 2025/0169318 A1
(43) Pub. Date: May 22, 2025

(54) DISPLAY SUBSTRATE, DISPLAY PANEL AND TILED DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Yunpeng Zhang, Beijing (CN); Chengchung Yang, Beijing (CN); Yangzhong Jing, Beijing (CN); Yucheng Chan, Beijing (CN); Xiangfei He, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/842,449

(22) PCT Filed: Sep. 26, 2023
(86) PCT No.: PCT/CN2023/121772

§ 371 Date: Aug. 29, 2024

(30) Foreign Application Priority Data
Oct. 28, 2022 (CN) 202211342645.4

(51) Int. Cl. H10K 59/35; H10K 59/122; H10K 59/18

(52) U.S. Cl. CPC H10K 59/353; H10K 59/122; H10K 59/18

(57) ABSTRACT

The displaying region of a displaying base board includes a center region containing first pixel units arranged in an array and an edge region containing second pixel units. The area of a light emitting region of each of the second pixel units is greater than the area of a light emitting region of each of the first pixel units. The displaying base board includes a first electrically conductive layer, and the first electrically conducting layer includes a plurality of anodes. Each of the pixel units includes a plurality of sub-pixels, and for the sub-pixels of the same color, the area of the orthographic projection on the substrate of each of the anodes of the sub-pixels located within the edge region is greater than the area of the orthographic projection on the substrate of each of the anodes of the sub-pixels located within the center region.

### CROSS REFERENCE TO RELEVANT APPLICATIONS

The present application claims the priority of the Chinese patent application filed on Oct. 28, 2022 before the Chinese Patent Office with the application number of 202211342645.4 and the title of “DISPLAY SUBSTRATE, DISPLAY PANEL AND TILED DISPLAY DEVICE”, which is incorporated herein in its entirety by reference.

### TECHNICAL FIELD

The present application relates to the technical field of displaying, and particularly relates to a displaying base board, a display panel and a spliced displaying device.

### BACKGROUND

With the development of the technique of displaying, organic-light-emitting-diode displaying devices (OLED), because of their advantages such as a wide color gamut, a high contrast, a low weigh, self-illumination and a wide visual angle, have already become a research hotspot of the major manufacturers and a trend of the technical development currently.

Currently, in OLED spliced displaying devices, because the splicing seam exists, the splitting sensation of the displayed frame caused by the splicing-seam position deteriorates the effect of displaying to a large extent.

### SUMMARY

The embodiments of the present application employ the following technical solutions:

In the first aspect, an embodiment of the present application provides a displaying base board, wherein the displaying base board comprises a displaying region;
the displaying region comprises a center region and an edge region surrounding the center region, the center region contains a plurality of first pixel units arranged in an array, the edge region contains a plurality of second pixel units, and at least one row of the second pixel units are arranged along a lateral side of the displaying base board;
an area of a light emitting region of each of the second pixel units is greater than an area of a light emitting region of each of the first pixel units;
the displaying base board comprises a substrate and a first electrically conducting layer located on the substrate, and the first electrically conducting layer comprises a plurality of anodes; and
each of the pixel units comprises a plurality of sub-pixels, and for the instances of the sub-pixels of a same color, an area of an orthographic projection on the substrate of each of the anodes of the sub-pixels located within the edge region is greater than an area of an orthographic projection on the substrate of each of the anodes of the sub-pixels located within the center region.

In the displaying base board according to an embodiment of the present application, the displaying base board comprises a first lateral side, a second lateral side, a third lateral side and a fourth lateral side that are sequentially connected, and the at least one row of the second pixel units are arranged along at least one of the first lateral side, the second lateral side, the third lateral side and the fourth lateral side.

In the displaying base board according to an embodiment of the present application, the displaying base board further comprises a pixel defining layer, the pixel defining layer comprises a plurality of first openings and a plurality of second openings, the first openings are located within the center region, and the second openings are located within the edge region;
a region encircled by an orthographic projection of an outer contour of each of the first openings on the substrate overlaps with the orthographic projection on the substrate of the anode of the each of the sub-pixels located within the center region, and a region encircled by an orthographic projection of an outer contour of each of the second openings on the substrate overlaps with the orthographic projection on the substrate of the anode of the each of the sub-pixels located within the edge region; and
for the instances of the sub-pixels of a same color, an area of a pattern of the orthographic projection of the outer contour of each of the first openings on the substrate is less than an area of a pattern of the orthographic projection of the outer contour of each of the second openings on the substrate.

In the displaying base board according to an embodiment of the present application, the first electrically conducting layer further comprises a plurality of connecting electrodes, orthographic projections of the connecting electrodes on the substrate and orthographic projections of the pixel units on the substrate do not overlap with each other, and the connecting electrodes are electrically connected to the anodes;
the pixel defining layer comprises a plurality of third openings, and regions encircled by orthographic projections of outer contours of the third openings on the substrate overlap with the orthographic projections of the connecting electrodes on the substrate;
a quantity of the third openings is equal to a quantity of the connecting electrodes; and
the connecting electrodes are located at least within the center region.

In the displaying base board according to an embodiment of the present application, some of the connecting electrodes are located within the center region, and some of the connecting electrodes are located within the edge region; and
a distribution density of the connecting electrodes located within the center region is greater than a distribution density of the connecting electrodes located within the edge region.

In the displaying base board according to an embodiment of the present application, some of the connecting electrodes are located within the center region, and some of the connecting electrodes are located within the edge region; and
a quantity of the connecting electrodes located within the center region is greater than a quantity of the connecting electrodes located within the edge region.

In the displaying base board according to an embodiment of the present application, each of the sub-pixels comprises a luminescent functional layer, and the luminescent functional layer is located on one side of the anodes that is farther from the substrate; and
for the instances of the sub-pixels of a same color, an area of a pattern of an orthographic projection on the substrate of each of the luminescent functional layers within the edge region is greater than an area of a pattern of an orthographic projection on the substrate of each of the luminescent functional layers within the center region.

In the displaying base board according to an embodiment of the present application, each of the luminescent functional layers comprises a luminescent sublayer and a functional sublayer; and
for the instances of the sub-pixels of a same color, an area of a pattern of an orthographic projection on the substrate of each of the luminescent sublayers within the edge region is equal to an area of a pattern of an orthographic projection on the substrate of each of the luminescent sublayers within the center region, and an area of a pattern of an orthographic projection on the substrate of each of the functional sublayers within the edge region is greater than an area of a pattern of an orthographic projection on the substrate of each of the functional sublayers within the center region.

In the displaying base board according to an embodiment of the present application,
within the center region, for a same one instance of the sub-pixels, the orthographic projection of the luminescent sublayer on the substrate and the orthographic projection of the functional sublayer on the substrate partially overlap; and
within the edge region, for a same one instance of the sub-pixels, the orthographic projection of the luminescent sublayer on the substrate is located within the orthographic projection of the functional sublayer on the substrate.

In the displaying base board according to an embodiment of the present application,
within the center region, the functional sublayers of the sub-pixels in a same one instance of the first pixel units are integral, and the functional sublayers in two neighboring instances of the first pixel units are disconnected; and
within the edge region, the functional sublayers of the sub-pixels in a same one instance of the second pixel units are integral, and the functional sublayers in at least two instances of the second pixel units are integral.

In the displaying base board according to an embodiment of the present application, if the functional sublayers in at least two instances of the second pixel units are integral, an orthographic projection on the substrate of the functional sublayers that are integral covers a region between two neighboring instances of the second pixel units; and
the orthographic projections of the connecting electrodes on the substrate and the orthographic projection on the substrate of the functional sublayers that are integral do not overlap with each other.

In the displaying base board according to an embodiment of the present application, the displaying base board further comprises a cathode layer, the cathode layer comprises a plurality of cathodes, the plurality of cathodes are integral, the cathode layer covers the pixel defining layer, and the cathode layer contacts and is conducted with the connecting electrodes.

In the displaying base board according to an embodiment of the present application, spacings between the light emitting regions of two neighboring instances of the first pixel units are equal, and spacings between the light emitting regions of two neighboring instances of the second pixel units are equal.

In the displaying base board according to an embodiment of the present application, all of spacings between the light emitting regions of any two neighboring instances of the pixel units are equal.

In the displaying base board according to an embodiment of the present application, N rings of the second pixel units are arranged along the lateral sides of the displaying base board; and
a pattern of an orthographic projection of the displaying region on the substrate comprises a first corner, a second corner, a third corner and a fourth corner, the functional sublayers of N*N instances of the second pixel units that are located at the first corner are integral, the functional sublayers of N*N instances of the second pixel units that are located at the second corner are integral, the functional sublayers of N*N instances of the second pixel units that are located at the third corner are integral, and the functional sublayers of N*N instances of the second pixel units that are located at the fourth corner are integral;
wherein N is greater than or equal to 2.

In the displaying base board according to an embodiment of the present application, the functional sublayers include at least one of a hole injection sublayer, a hole transporting sublayer, an electron injection sublayer, an electron transporting sublayer and a charge transporting sublayer.

In the second aspect, an embodiment of the present application provides a display panel, wherein the display panel comprises the displaying base board according to any one of the embodiments in the first aspect.

In the third aspect, an embodiment of the present application provides a spliced displaying device, wherein the spliced displaying device comprises at least two instances of the display panel in the second aspect.

The above description is merely a summary of the technical solutions of the present application. In order to more clearly know the elements of the present application to enable the implementation according to the contents of the description, and in order to make the above and other purposes, features and advantages of the present application more apparent and understandable, the particular embodiments of the present application are provided below.

### BRIEF DESCRIPTION OF THE DRAWINGS

In order to more clearly illustrate the technical solutions of the embodiments of the present application, the figures that are required to describe the embodiments will be briefly described below. Apparently, the figures that are described below are embodiments of the present application, and a person skilled in the art can obtain other figures according to these figures without paying creative work.

FIGS. 1 and 2 are schematic structural diagrams of two spliced displaying devices in the related art;

FIG. 3 is a schematic diagram of the principle of optical seamless splicing of a spliced displaying device in the related art;

FIG. 4 is a schematic top structural diagram of a displaying base board according to an embodiment of the present application;

FIG. 5 is a schematic top structural diagram of a first pixel unit according to an embodiment of the present application;

FIG. 6 is a schematic top structural diagram of a second pixel unit according to an embodiment of the present application;

FIG. 7 is a schematic comparison diagram of the structures of a first pixel unit and a second pixel unit according to an embodiment of the present application;

FIG. 8 is a schematic cross-sectional structural diagram along M1M2 of FIG. 4;

FIG. 9 is a schematic top structural diagram of an anode layer according to an embodiment of the present application;

FIG. 10 is a schematic top structural diagram of a pixel defining layer according to an embodiment of the present application;

FIG. 11 is a schematic top structural diagram after stacking of a pixel defining layer and a functional sublayer according to an embodiment of the present application;

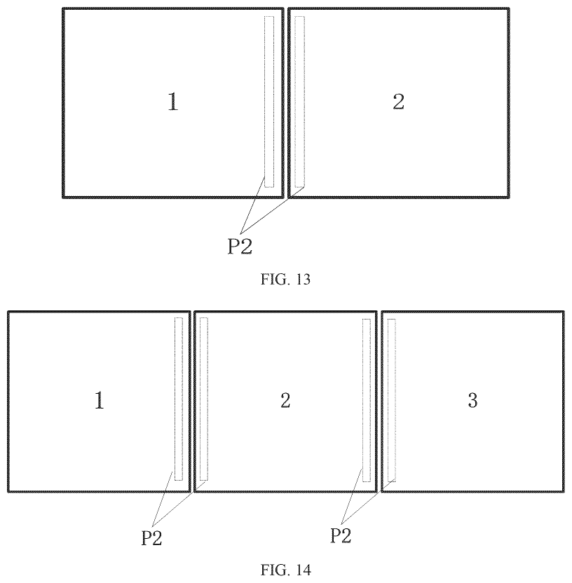

FIG. 12 is a schematic top structural diagram after stacking of a pixel defining layer and a luminescent sublayer according to an embodiment of the present application; and

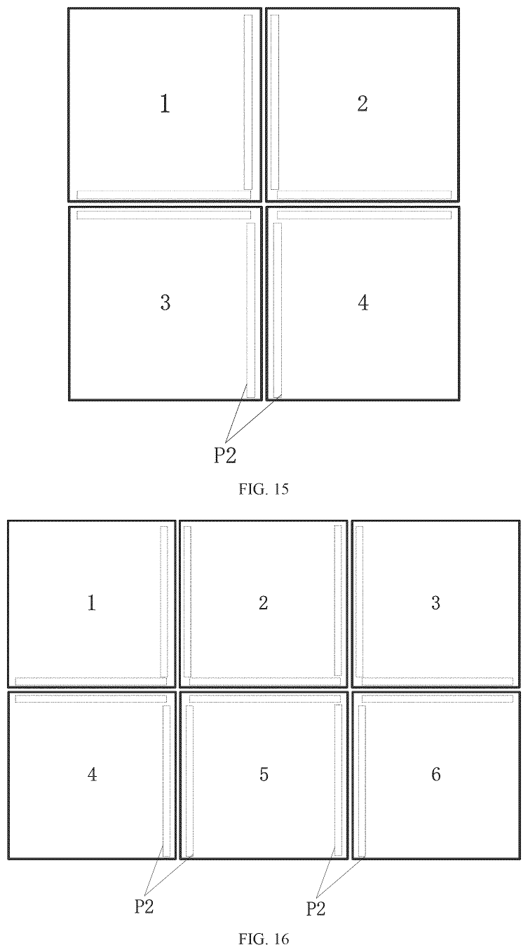

FIGS. 13-17 are schematic diagrams of five modes of splicing according to embodiments of the present application.

### DETAILED DESCRIPTION

The technical solutions of the embodiments of the present application will be clearly and completely described below with reference to the drawings of the embodiments of the present application. Apparently, the described embodiments are merely certain embodiments of the present application, rather than all of the embodiments. All of the other embodiments that a person skilled in the art obtains on the basis of the embodiments of the present application without paying creative work fall within the protection scope of the present application.

Unless stated otherwise in the context, throughout the description and the claims, the term “comprise” is interpreted as the meaning of opened containing, i.e., “including but not limited to”. In the description of the present disclosure, the terms “one embodiment”, “some embodiments”, “exemplary embodiment”, “example”, “specific example” or “some examples” are intended to indicate that specific features, structures, materials or characteristics related to the embodiment or example are comprised in at least one embodiment or example of the present application. The illustrative indication of the above terms does not necessarily refer to the same one embodiment or example. Moreover, the specific features, structures, materials or characteristics may be comprised in any one or more embodiments or examples in any suitable manner.

In the embodiments of the present application, terms such as “first” and “second” are used to distinguish identical items or similar items that have substantially the same functions and effects, merely in order to clearly describe the technical solutions of the embodiments of the present application, and should not be construed as indicating or implying the degrees of importance or implicitly indicating the quantity of the specified technical features.

In the description, “parallel” refers to the state in which the angle formed by two straight lines is not less than −10° and not greater than 10°, and thus also includes the state in which the angle is not less than −5° and not greater than 5°. Furthermore, “perpendicular” refers to the state in which the angle formed by two straight lines is not less than 80° and not greater than 100°, and thus also includes the state in which the angle is not less than 85° and not greater than 95°.

The polygons in the description are not the strictly defined polygons, may be an approximate triangle, parallelogram, trapezoid, pentagon, hexagon and so on, and may have some small deformations caused by tolerance.

The “same one layer” in the description refers to the relation between multiple film layers that are formed by using the same one material after the same one step (for example, a one-step patterning step). The “same one layer” used herein does not always refer to that the thicknesses of a plurality of film layers are equal or that the heights in a cross-sectional view of a plurality of film layers are equal.

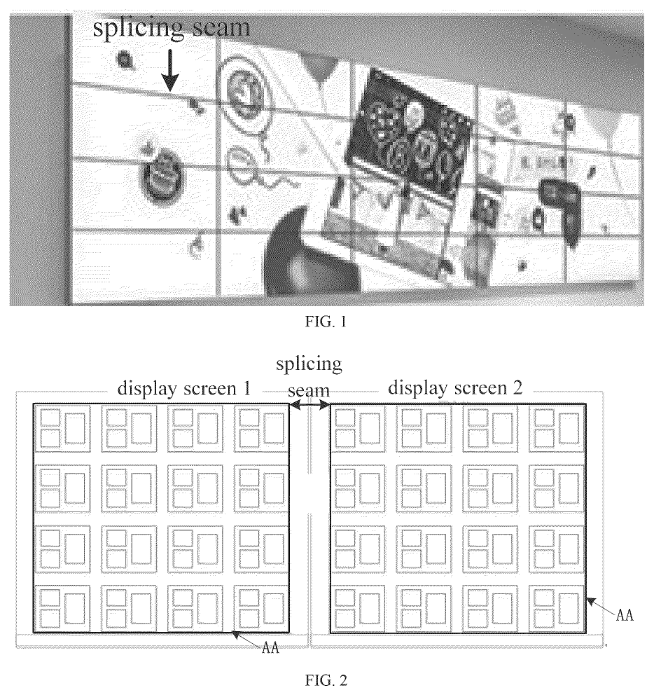

With the development of the industries such as outdoor advertising and indoor education, large-size display products have become an important branch of the display industry. As shown in FIG. 1, a typical indoor spliced screen is formed by splicing a plurality of display screens, for example, by splicing a plurality of LCD (Liquid Crystal Display) display screens, or by splicing a plurality of Mini LED (Mini Light Emitting Diode) display screens. When LCD display screens are used, because the border frames are large, the splicing seam is obvious, which is adverse to the displaying. Moreover, the Mini LED display screens, because of the big-mass transferring, have huge process difficulty and cost. Therefore, OLED (Organic Light Emitting Diode) display screens can become the primary choice of spliced screens.

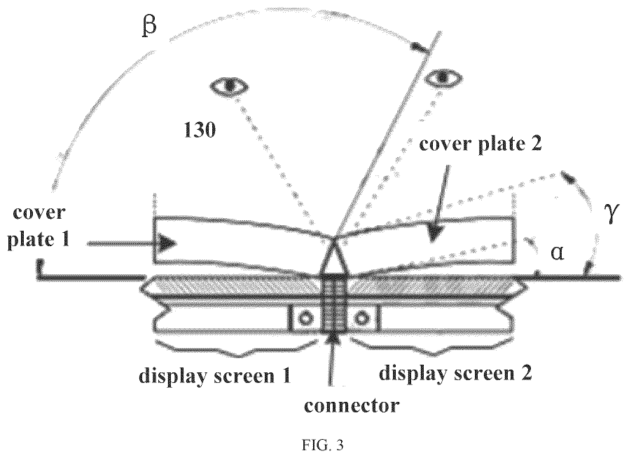

FIG. 2 shows a schematic structural diagram of a typical OLED spliced display screen. The spliced display screen is formed by splicing a plurality of independent display screens, and two spliced screens have a splicing seam therebetween. The area of the splicing seam cannot display the contents, and the size of the splicing seam directly influences the effect of displaying, and causes splitting sensation in the displaying. As shown in FIG. 3, in the related art, by using the principle of optical refraction, cover plates having a radian (for example, a cover plate 1 and a cover plate 2) are provided on the display screens, a hollowed-out structure similar to a trigonal prism is formed at the position where the two cover plates contact, and the light rays emitted by the pixel units within the edge regions of a display screen 1 and a display screen 2 are refracted to the splicing-seam position. As a result, from the perspective of the viewer, the splicing-seam position can display frames, thereby ameliorating the problem of the splitting sensation of the frames. Further, in order to increase the brightness uniformity of the spliced display screen, the emitted-light brightnesses of the pixel units closer to the splicing-seam position are required to be set higher (for example, by controlling the voltages of the anodes at the position to be higher), to compensate for the brightness at the splicing-seam position. Therefore, the pixel units within the edge regions of the display screens are easily damaged, and the lives of the display screens are highly reduced.

In view of the above, the embodiments of the present application provide a displaying base board, a display panel and a spliced displaying device, wherein the displaying base board comprises a displaying region; the displaying region comprises a center region and an edge region surrounding the center region, the center region contains a plurality of first pixel units arranged in an array, the edge region contains a plurality of second pixel units, and at least one row of the second pixel units are arranged along a lateral side of the displaying base board; the area of a light emitting region of each of the second pixel units is greater than the area of a light emitting region of each of the first pixel units; the displaying base board comprises a substrate and a first electrically conducting layer located on the substrate, and the first electrically conducting layer comprises a plurality of anodes; and each of the pixel units comprises a plurality of sub-pixels, and for the sub-pixels of the same color, the area of the orthographic projection on the substrate of each of the anodes of the sub-pixels located within the edge region is greater than the area of the orthographic projection on the substrate of each of the anodes of the sub-pixels located within the center region.

Accordingly, by, in the displaying base board, configuring that the area of the light emitting region of each of the second pixel units within the edge region is greater than the area of the light emitting region of each of the first pixel units within the center region, and by configuring that the area of the orthographic projection on the substrate of each of the anodes of the sub-pixels located within the edge region is greater than the area of the orthographic projection on the substrate of each of the anodes of the sub-pixels located within the center region, when the display panel is controlled to display, it may be configured that the brightnesses of all of the pixel units are equal (for example, by configuring that the voltages of the anodes of all of the pixel units are equal). Because the area of the light emitting region of each of the second pixel units within the edge region is greater than the area of the light emitting region of each of the first pixel units within the center region, the total intensity of the light rays of the second pixel units is greater than the total intensity of the light rays of the first pixel units. Therefore, when the spliced displaying device is formed, the second pixel units within the edge region, after compensating the brightness at the splicing-seam position, can maintain the brightness of the positions themselves. That does not only ameliorate the problem of the splitting sensation of the frame at the splicing-seam position and ensure the brightness uniformity of the spliced displaying device, but also can prolong the service life of the spliced displaying device and improve the product quality.

The displaying base board, the display panel and the spliced displaying device according to the embodiments of the present application will be described in detail below with reference to the drawings.

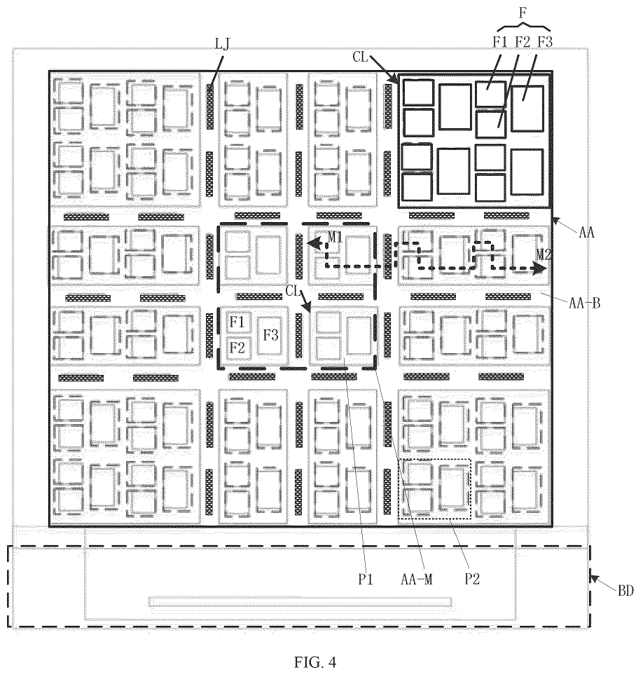

An embodiment of the present application provides a displaying base board. As shown in FIG. 4, the displaying base board comprises a displaying region AA.

The displaying region AA comprises a center region AA-M and an edge region AA-B surrounding the center region AA-M, the center region AA-M contains a plurality of first pixel units P1 arranged in an array, the edge region AA-B contains a plurality of second pixel units P2, and at least one row of the second pixel units P2 are arranged along a lateral side of the displaying base board.

The area of a light emitting region F of each of the second pixel units P2 is greater than the area of a light emitting region F of each of the first pixel units P1.

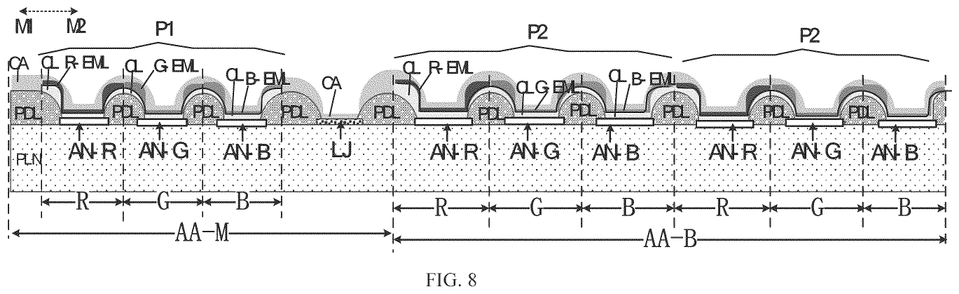

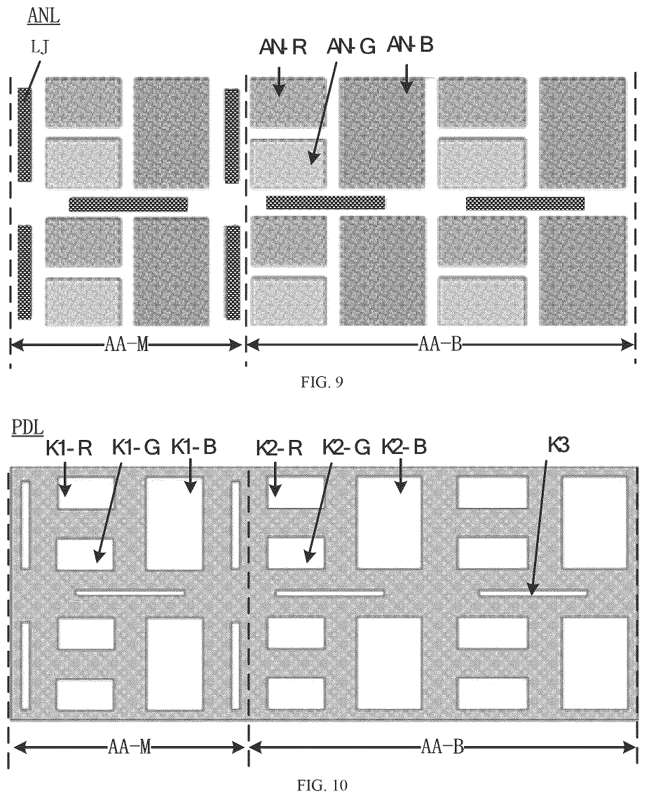

Referring to FIGS. 8 and 9, the displaying base board comprises a substrate and a first electrically conducting layer ANL located on the substrate, and the first electrically conducting layer ANL comprises a plurality of anodes AN. Each of the pixel units comprises a plurality of sub-pixels, and for the sub-pixels of the same color, the area of the orthographic projection on the substrate of each of the anodes AN of the sub-pixels located within the edge region AA-B is greater than the area of the orthographic projection on the substrate of each of the anodes AN of the sub-pixels located within the center region AA-M. FIG. 8 is a cross-sectional view along M1M2 of FIG. 4.

The displaying region (Active Area, AA) of the displaying base board refers to the region used to implement the displaying. The light emitting region (also referred to as a pixel opening region) refers to the region where the OLED units are provided and that actually emits the light rays. It can be known according to the related art that each of the OLED units comprises an anode (Anode), an organic luminescent functional layer and a cathode (Cathode). The non-light emitting region refers to the region within the displaying region AA other than the light emitting region, within which region a pixel defining layer and a pixel circuit may be provided, and the pixel circuit may comprise TFTs (Thin Film Transistor), grid lines, data lines and so on.

The sizes of the center region AA-M and the edge region AA-B surrounding the center region AA-M are not limited herein. If the size of the displaying region AA has been fixed, the size of the center region AA-M is decided by the size of the edge region AA-B, and the size of the edge region AA-B is decided by the size and the quantity of the second pixel units P2. In some embodiments, if the sizes of the first pixel units P1 and the second pixel units P2 are equal, the size of the edge region AA-B is decided by the quantity of the second pixel units P2.

The edge region AA-B may be an annular region.

Each of the first pixel units P1 comprises a plurality of sub-pixels. Each of the second pixel units P2 comprises a plurality of sub-pixels. In some embodiments, the quantity of the sub-pixels comprised by the first pixel unit P1 and the quantity of the sub-pixels comprised by the second pixel unit P2 are equal. As an example, each of the first pixel unit P1 and the second pixel unit P2 comprises three sub-pixels, wherein, for example, the three sub-pixels are a red-color sub-pixel, a green-color sub-pixel and a blue-color sub-pixel. In some other embodiments, the quantity of the sub-pixels comprised by the first pixel unit P1 and the quantity of the sub-pixels comprised by the second pixel unit P2 are unequal. As an example, the first pixel unit P1 comprises three sub-pixels, wherein, for example, the three sub-pixels are a red-color sub-pixel, a green-color sub-pixel and a blue-color sub-pixel, and the second pixel unit P2 comprises four sub-pixels, wherein, for example, the four sub-pixels are a red-color sub-pixel, a green-color sub-pixel, a blue-color sub-pixel and a white-color sub-pixel. It should be noted that the description describes by taking the case as an example in which the quantity of the sub-pixels comprised by the first pixel unit P1 and the quantity of the sub-pixels comprised by the second pixel unit P2 are equal.

If each of the first pixel unit P1 and the second pixel unit P2 comprises three sub-pixels, wherein, for example, the three sub-pixels are a red-color sub-pixel, a green-color sub-pixel and a blue-color sub-pixel, in some embodiments, the arrangement mode of the three sub-pixels in the first pixel unit P1 and the arrangement mode of the three sub-pixels in the second pixel unit P2 are different. In some embodiments, the designed patterns of the sub-pixels of the same color in the first pixel unit P1 and the second pixel unit P2 are different; for example, the designed shapes of the red-color sub-pixels are different. It should be noted that the description describes by taking the case as an example in which the arrangement mode of the three sub-pixels in the first pixel unit P1 and the arrangement mode of the three sub-pixels in the second pixel unit P2 are the same, and the designed shapes of the sub-pixels of the same color in the first pixel unit P1 and the second pixel unit P2 are the same, but that is not a limitation on the arrangement mode of the three sub-pixels in the first pixel unit P1 and the arrangement mode of the three sub-pixels in the second pixel unit P2, and is not a limitation on the designed shapes of the sub-pixels of the same color in the first pixel unit P1 and the second pixel unit P2.

If each of the pixel units comprises a plurality of sub-pixels, the light emitting region F of each of the pixel units may comprise a plurality of light emitting sub-regions, wherein the quantity of the light emitting sub-regions is equal to the quantity of the sub-pixels.

That the area of the light emitting region F of each of the second pixel units P2 is greater than the area of the light emitting region F of each of the first pixel units P1 refers to that the total area of the light emitting region F of one second pixel unit P2 is greater than the total area of the light emitting region F of one first pixel unit P1.

As an example, the light emitting region F comprises a light emitting sub-region F1, a light emitting sub-region F2 and a light emitting sub-region F3, wherein the area of the light emitting sub-region F1 of the second pixel unit P2 is greater than the area of the light emitting sub-region F1 of the first pixel unit P1, the area of the light emitting sub-region F2 of the second pixel unit P2 is greater than the area of the light emitting sub-region F2 of the first pixel unit P1, and the area of the light emitting sub-region F3 of the second pixel unit P2 is greater than the area of the light emitting sub-region F3 of the first pixel unit P1. The light emitting sub-region F1, the light emitting sub-region F2 and the light emitting sub-region F3 correspond to the light emitting sub-region of the red-color sub-pixel, the light emitting sub-region of the green-color sub-pixel and the light emitting sub-region of the blue-color sub-pixel respectively.

In the displaying base board according to an embodiment of the present application, the area of the planar pattern of the second pixel unit P2 is greater than the area of the planar pattern of the first pixel unit P1. In the displaying base board according to an embodiment of the present application, the area of the planar pattern of the second pixel unit P2 is equal to the area of the planar pattern of the first pixel unit P1. The planar pattern refers to the pattern of the orthographic projection of the pixel unit on the substrate.

That at least one row of the second pixel units P2 are arranged along a lateral side of the displaying base board includes that one row of the second pixel units P2 are arranged along a lateral side of the displaying base board, or that two or more rows of the second pixel units P2 are arranged along a lateral side of the displaying base board.

If two or more rows of the second pixel units P2 are arranged along a lateral side of the displaying base board, the arrangement directions of the plurality of rows of the second pixel units P2 are not limited herein.

As an example, if two rows of the second pixel units P2 are arranged along a lateral side of the displaying base board, the directions of extension of the two rows of the second pixel units P2 may be the same. For example, both of the two rows of the second pixel units P2 are arranged along the lateral side of the left side of the displaying base board. As another example, the two rows of the second pixel units P2 are arranged along the lateral side of the left side and the lateral side of the right side of the displaying base board.

As an example, if two rows of the second pixel units P2 are arranged along a lateral side of the displaying base board, the directions of extension of the two rows of the second pixel units P2 may be different. For example, the two rows of the second pixel units P2 are arranged along the lateral side of the left side and the lateral side of the upper side of the displaying base board. As another example, the two rows of the second pixel units P2 are arranged along the lateral side of the left side and the lateral side of the lower side of the displaying base board. Certainly, other cases may exist, and are not discussed further herein.

In practical applications, if more second pixel units P2 are provided within the edge region AA-B, the total intensity of the light rays of the second pixel units P2 closer to the splicing-seam position is higher, and the effect of the compensation for the light rays at the splicing-seam position is better.

In addition, the quantity of the lateral sides of the displaying base board is not limited herein, and the quantity of the lateral sides of the displaying base board is related to the shape of the displaying base board. In some embodiments, the shape of the displaying base board may be a polygon, for example, a tetragon and a pentagon. In some embodiments, the shape of the displaying base board may comprise an arc shape; for example, the shape of the displaying base board may be a combination of a polygon and an arc shape. That may be decided particularly according to the design of the display product.

As an example, the area of the orthographic projection on the substrate of the anode AN-R of the red-color sub-pixel of the second pixel unit P2 is greater than the area of the orthographic projection on the substrate of the anode AN-R of the red-color sub-pixel of the first pixel unit P1, the area of the orthographic projection on the substrate of the anode AN-G of the green-color sub-pixel of the second pixel unit P2 is greater than the area of the orthographic projection on the substrate of the anode AN-G of the green-color sub-pixel of the first pixel unit P1, and the area of the orthographic projection on the substrate of the anode AN-B of the blue-color sub-pixel of the second pixel unit P2 is greater than the area of the orthographic projection on the substrate of the anode AN-B of the blue-color sub-pixel of the first pixel unit P1.

The embodiments of the present application provide a displaying base board. By, in the displaying base board, configuring that the area of the light emitting region F of each of the second pixel units P2 within the edge region AA-B is greater than the area of the light emitting region of each of the first pixel units P1 within the center region AA-M, and by configuring that the area of the orthographic projection on the substrate of each of the anodes AN of the sub-pixels located within the edge region AA-B is greater than the area of the orthographic projection on the substrate of each of the anodes AN of the sub-pixels located within the center region AA-M, when the display panel formed by the displaying base board is controlled to display, it may be configured that the brightnesses of all of the pixel units are equal (for example, by configuring that the voltages of the anodes of all of the pixel units are equal). Because the area of the light emitting region F of each of the second pixel units P2 within the edge region AA-B is greater than the area of the light emitting region F of each of the first pixel units P1 within the center region AA-M, the total intensity of the light rays of the second pixel units P2 is greater than the total intensity of the light rays of the first pixel units P1. Therefore, when the spliced displaying device is formed, the second pixel units P2 within the edge region AA-B, after compensating the brightness at the splicing-seam position, can maintain the brightness of the positions themselves. That does not only ameliorate the problem of the splitting sensation of the frame at the splicing-seam position and ensure the brightness uniformity of the spliced displaying device, but also can prolong the service life of the spliced displaying device and improve the product quality.

In some embodiments, the shape of the displaying base board is a tetragon, for example, a square or a rectangle, in which case the displaying base board comprises a first lateral side, a second lateral side, a third lateral side and a fourth lateral side that are sequentially connected, and the at least one row of the second pixel units P2 are arranged along at least one of the first lateral side, the second lateral side, the third lateral side and the fourth lateral side.

That the at least one row of the second pixel units P2 are arranged along at least one of the first lateral side, the second lateral side, the third lateral side and the fourth lateral side includes but is not limited to the following cases:

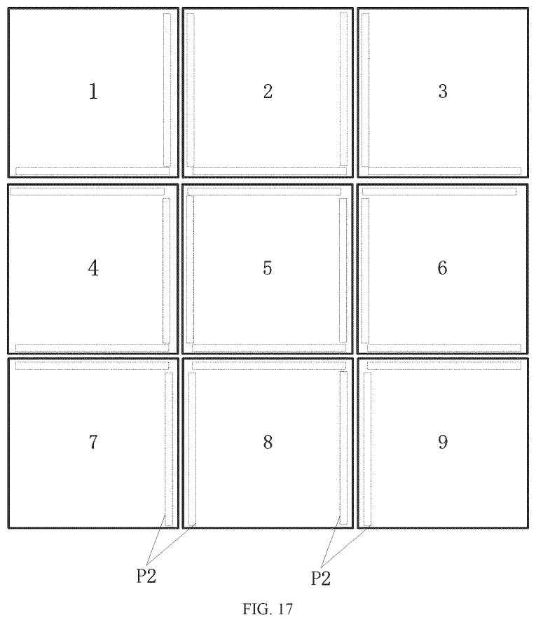

FIGS. 13-17 illustrate five modes of splicing. The case is taken as an example for the description in which the lateral side of the left side of a displaying base board in the figures is the first lateral side, the lateral side of the upper side is the second lateral side, the lateral side of the right side is the third lateral side, and the lateral side of the lower side is the fourth lateral side.

In a first case, as shown in FIG. 13, regarding the displaying base board 1 on the left, at least one row of the second pixel units P2 are arranged on its third lateral side. Regarding the displaying base board 2 on the right, at least one row of the second pixel units P2 are arranged on its first lateral side.

In a second case, as shown in FIG. 14, regarding the displaying base board 1 on the left, at least one row of the second pixel units P2 are arranged on its third lateral side. Regarding the displaying base board 2 in the middle, at least one row of the second pixel units P2 are arranged on its first lateral side, and at least one row of the second pixel units P2 are arranged on its third lateral side. Regarding the displaying base board 3 on the right, at least one row of the second pixel units P2 are arranged on its first lateral side.

In a third case, as shown in FIG. 15, regarding the displaying base board 1 at the top left corner, at least one row of the second pixel units P2 are arranged on its third lateral side, and at least one row of the second pixel units P2 are arranged on its fourth lateral side. Regarding the displaying base board 2 at the top right corner, at least one row of the second pixel units P2 are arranged on its first lateral side, and at least one row of the second pixel units P2 are arranged on its fourth lateral side. Regarding the displaying base board 3 at the bottom left corner, at least one row of the second pixel units P2 are arranged on its second lateral side, and at least one row of the second pixel units P2 are arranged on its third lateral side. Regarding the displaying base board 4 at the bottom right corner, at least one row of the second pixel units P2 are arranged on its first lateral side, and at least one row of the second pixel units P2 are arranged on its fourth lateral side.

In a fourth case, as shown in FIG. 16, regarding the displaying base board 2 at the top middle corner, at least one row of the second pixel units P2 are arranged on its first lateral side, at least one row of the second pixel units P2 are arranged on its third lateral side, and at least one row of the second pixel units P2 are arranged on its fourth lateral side. Regarding the displaying base board 5 at the bottom middle corner, at least one row of the second pixel units P2 are arranged on its first lateral side, at least one row of the second pixel units P2 are arranged on its second lateral side, and at least one row of the second pixel units P2 are arranged on its third lateral side.

In a fifth case, as shown in FIG. 17, regarding the displaying base board 5 at the middle position, on its first lateral side, second lateral side, third lateral side and fourth lateral side are individually provided at least one row of the second pixel units P2.

In some embodiments, in the displaying base board 5 at the middle position shown in FIG. 17, a ring of the second pixel units P2 are arranged on the lateral sides of the displaying base board. It can be understood that one row of the second pixel units P2 are arranged on the first lateral side of the displaying base board 5, one row of the second pixel units P2 are arranged on the second lateral side of the displaying base board 5, one row of the second pixel units P2 are arranged on the third lateral side of the displaying base board 5, and one row of the second pixel units P2 are arranged on the fourth lateral side of the displaying base board 5. The four rows of the second pixel units P2 arranged on the four lateral sides form a ring of the second pixel units P2. FIG. 4 illustrates by taking the case as an example in which two rings of the second pixel units P2 are arranged along the lateral sides of the displaying base board.

In the displaying base board according to the embodiments of the present application, the at least one row of the second pixel units P2 are arranged along at least one of the first lateral side, the second lateral side, the third lateral side and the fourth lateral side. By configuring that the area of the light emitting region F of each of the second pixel units P2 within the edge region AA-B is greater than the area of the light emitting region of each of the first pixel units P1 within the center region AA-M, because the area of the light emitting region F of each of the second pixel units P2 within the edge region AA-B is greater than the area of the light emitting region F of each of the first pixel units P1 within the center region AA-M, the total intensity of the light rays of the second pixel units P2 is greater than the total intensity of the light rays of the first pixel units P1. Therefore, when the spliced displaying device is formed, the second pixel units P2 within the edge region AA-B, after compensating the brightness at the splicing-seam position, can maintain the brightness of the positions themselves. That does not only ameliorate the problem of the splitting sensation of the frame at the splicing-seam position and ensure the brightness uniformity of the spliced displaying device, but also can prolong the service life of the spliced displaying device and improve the product quality.

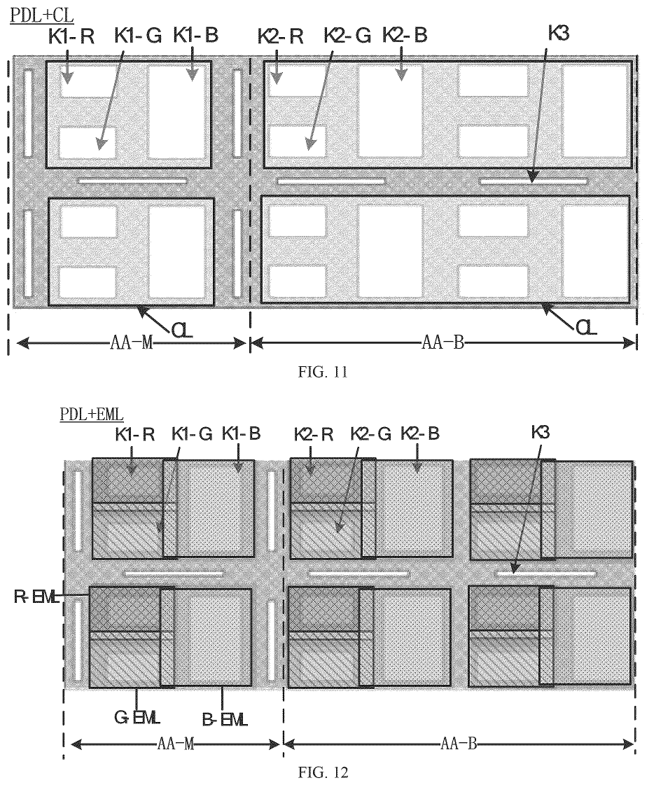

In the displaying base board according to an embodiment of the present application, referring to FIGS. 8 and 10, the displaying base board further comprises a pixel defining layer PDL, the pixel defining layer PDL comprises a plurality of first openings K1 and a plurality of second openings K2, the first openings K1 are located within the center region, and the second openings K2 are located within the edge region.

As shown in FIG. 8, the region encircled by the orthographic projection of the outer contour of each of the first openings K1 on the substrate overlaps with the orthographic projection on the substrate of the anode AN of the each of the sub-pixels located within the center region AA-M, and the region encircled by the orthographic projection of the outer contour of each of the second openings K2 on the substrate overlaps with the orthographic projection on the substrate of the anode AN of the each of the sub-pixels located within the edge region AA-B. For the sub-pixels of the same color, the area of the pattern of the orthographic projection of the outer contour of each of the first openings K1 on the substrate is less than the area of the pattern of the orthographic projection of the outer contour of each of the second openings K2 on the substrate.

As an example, that the region encircled by the orthographic projection of the outer contour of each of the first openings K1 on the substrate overlaps with the orthographic projection on the substrate of the anode AN of the each of the sub-pixels located within the center region AA-M includes the following cases:

In a first case, the region encircled by the orthographic projection of the outer contour of the first opening K1-R on the substrate overlaps with the orthographic projection on the substrate of the anode AN-R of the sub-pixel R located within the center region AA-M.

In a second case, the region encircled by the orthographic projection of the outer contour of the first opening K1-G on the substrate overlaps with the orthographic projection on the substrate of the anode AN-G of the sub-pixel G located within the center region AA-M.

In a third case, the region encircled by the orthographic projection of the outer contour of the first opening K1-B on the substrate overlaps with the orthographic projection on the substrate of the anode AN-B of the sub-pixel B located within the center region AA-M.

That, for the sub-pixels of the same color, the area of the pattern of the orthographic projection of the outer contour of each of the first openings K1 on the substrate is less than the area of the pattern of the orthographic projection of the outer contour of each of the second openings K2 on the substrate includes the following cases:

In a first case, regarding the red-color sub-pixel R, the area of the pattern of the orthographic projection of the outer contour of the first opening K1-R on the substrate is less than the area of the pattern of the orthographic projection of the outer contour of the second opening K2-R on the substrate.

In a second case, regarding the green-color sub-pixel G, the area of the pattern of the orthographic projection of the outer contour of the first opening K1-G on the substrate is less than the area of the pattern of the orthographic projection of the outer contour of the second opening K2-G on the substrate.

In a third case, regarding the blue-color sub-pixel B, the area of the pattern of the orthographic projection of the outer contour of the first opening K1-B on the substrate is less than the area of the pattern of the orthographic projection of the outer contour of the second opening K2-B on the substrate.

In the embodiments of the present application, the sizes of the first openings K1 or the second openings K2 decide the effective contact area between the luminescent functional layers and the anodes AN, and thus decide the areas of the light emitting regions F. For the sub-pixels of the same color, by configuring that the area of the pattern of the orthographic projection of the outer contour of each of the first openings K1 on the substrate is less than the area of the pattern of the orthographic projection of the outer contour of each of the second openings K2 on the substrate, the effective contact area between the luminescent functional layers and the anodes AN of the second pixel units P2 located within the edge region AA-B can be greater than the effective contact area between the luminescent functional layers and the anodes AN of the first pixel units P1 located within the center region AA-M, which can ensure that the area of the light emitting region F of each of the second pixel units P2 located within the edge region AA-B is greater than the area of the light emitting region F of each of the first pixel units P1 located within the center region AA-M.

In the displaying base board according to an embodiment of the present application, referring to FIGS. 8 and 9, the first electrically conducting layer ANL further comprises a plurality of connecting electrodes LJ, the orthographic projections of the connecting electrodes LJ on the substrate and the orthographic projections of the pixel units on the substrate do not overlap with each other, and the connecting electrodes LJ are electrically connected to the anodes AN.

Referring to FIGS. 8 and 10, the pixel defining layer PDL comprises a plurality of third openings K3, and the regions encircled by the orthographic projections of outer contours of the third openings K3 on the substrate overlap with the orthographic projections of the connecting electrodes LJ on the substrate. The quantity of the third openings K3 is equal to the quantity of the connecting electrodes LJ.

The connecting electrodes LJ are located at least within the center region AA-M.

In the embodiments of the present application, by providing the connecting electrodes LJ within the displaying region, the connecting electrodes LJ are conducted with the cathodes and the anodes, thereby forming the closed loops of the pixel driving circuits. As compared with the related art, in which the connecting electrodes LJ are provided within the peripheral region (for example, annular connecting electrodes, also referred to as cathode rings), that can significantly reduce the size of the border frame, thereby further reducing the practical size of the splicing seam, to improve the effect of displaying.

That the connecting electrodes LJ are located at least within the center region AA-M includes but is not limited to the following cases:

In a first case, the connecting electrodes LJ are located merely within the center region AA-M.

In a second case, the connecting electrodes LJ are not only located within the center region AA-M, but also may extend into the edge region AA-B outside the center region AA-M of the displaying region AA.

In the displaying base board according to an embodiment of the present application, as shown in FIG. 4, some of the connecting electrodes LJ are located within the center region AA-M, and some of the connecting electrodes LJ are located within the edge region AA-B. The distribution density of the connecting electrodes LJ located within the center region AA-M is greater than the distribution density of the connecting electrodes LJ located within the edge region AA-B.

In the displaying base board according to an embodiment of the present application, as shown in FIG. 4, some of the connecting electrodes LJ are located within the center region AA-M, and some of the connecting electrodes LJ are located within the edge region AA-B. The quantity of the connecting electrodes LJ located within the center region AA-M is greater than the quantity of the connecting electrodes LJ located within the edge region AA-B.

In the embodiments of the present application, by configuring that the distribution density of the connecting electrodes LJ located within the center region AA-M is greater than the distribution density of the connecting electrodes LJ located within the edge region AA-B, or configuring that the quantity of the connecting electrodes LJ located within the center region AA-M is greater than the quantity of the connecting electrodes LJ located within the edge region AA-B, the edge region AA-B can have a larger design room, so as to further increase the areas of the light emitting regions of the second pixel units P2 within the edge region AA-B, and reduce the practical size of the splicing seam, thereby improving the effect of displaying, and prolonging the service life of the product.

In the displaying base board according to an embodiment of the present application, each of the sub-pixels comprises a luminescent functional layer EL, and the luminescent functional layer EL is located on the side of the anodes AN that is farther from the substrate.

For the sub-pixels of the same color, the area of the pattern of the orthographic projection on the substrate of each of the luminescent functional layers EL within the edge region AA-B is greater than the area of the pattern of the orthographic projection on the substrate of each of the luminescent functional layers EL within the center region AA-M.

As an example, regarding the red-color sub-pixel R, the area of the pattern of the orthographic projection on the substrate of the luminescent functional layer EL-R within the edge region AA-B is greater than the area of the pattern of the orthographic projection on the substrate of the luminescent functional layer EL-R within the center region AA-M. Regarding the green-color sub-pixel G, the area of the pattern of the orthographic projection on the substrate of the luminescent functional layer EL-G within the edge region AA-B is greater than the area of the pattern of the orthographic projection on the substrate of the luminescent functional layer EL-G within the center region AA-M. Regarding the blue-color sub-pixel B, the area of the pattern of the orthographic projection on the substrate of the luminescent functional layer EL-B within the edge region AA-B is greater than the area of the pattern of the orthographic projection on the substrate of the luminescent functional layer EL-B within the center region AA-M.

In the embodiments of the present application, for the sub-pixels of the same color, by configuring that the area of the pattern of the orthographic projection on the substrate of each of the luminescent functional layers EL within the edge region AA-B is greater than the area of the pattern of the orthographic projection on the substrate of each of the luminescent functional layers EL within the center region AA-M, it can be ensured that the area of the light emitting region F of each of the second pixel units P2 located within the edge region AA-B is greater than the area of the light emitting region F of each of the first pixel units P1 located within the center region AA-M, which can reduce the practical size of the splicing seam, thereby improving the effect of displaying, and prolonging the service life of the product.

In the displaying base board according to an embodiment of the present application, each of the luminescent functional layers EL comprises a luminescent sublayer EML and a functional sublayer CL.

The functional sublayers CL may include at least one of a hole injection sublayer, a hole transporting sublayer, an electron injection sublayer, an electron transporting sublayer and a charge transporting sublayer.

As an example, the luminescent functional layer EL may comprise a hole injection sublayer (HIL), a hole transporting layer (HTL), an organic transition buffer layer (Prime), a luminescent sublayer (for example, a blue-color EML, a red-color EML and a green-color EML), a hole blocking layer (HBL) and an electron injection layer (EIL) that are arranged sequentially in stack.

As another example, the luminescent functional layer EL may comprise a first luminescent sublayer, a second luminescent sublayer, and a charge transporting sublayer (CGL) located between the first luminescent sublayer (EML1) and the second luminescent sublayer (EML2), and, certainly, may further comprise a hole injection sublayer (HIL), a hole transporting sublayer (HTL), an electron injection sublayer (EIL) and an electron transporting sublayer (ETL). In this case, the displaying base board can realize a configuration of double-layer luminescence (Tandem EL).

It should be noted that, in the embodiments of the present application, in order to facilitate to describe the luminescent sublayers EML and the functional sublayers CL, in FIG. 8, the functional sublayers CL are drawn on the side of the luminescent sublayers (for example, R-EML, G-EML and B-EML) that is farther from the substrate. In practical applications, some of the functional sublayers CL are located between the luminescent sublayers and the substrate, and some of the functional sublayers CL are located on the side of the luminescent sublayers that is farther from the substrate, which may particularly refer to the description in the related art.

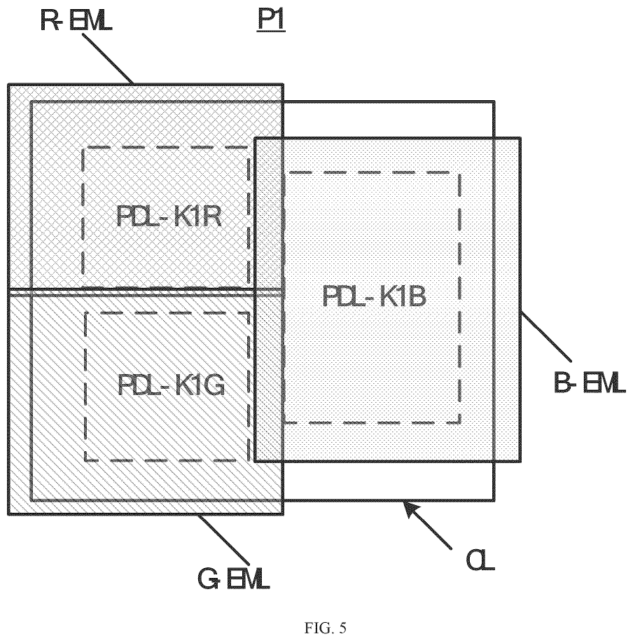

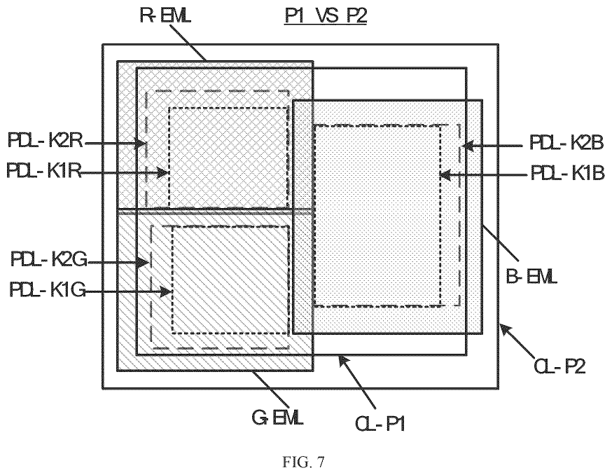

Referring to FIGS. 5, 6 and 7, for the sub-pixels of the same color, the area of the pattern of the orthographic projection on the substrate of each of the luminescent sublayers (for example, R-EML, G-EML and B-EML) within the edge region AA-B (the second pixel units P2) is equal to the area of the pattern of the orthographic projection on the substrate of each of the luminescent sublayers (for example, R-EML, G-EML and B-EML) within the center region AA-M (the first pixel units P1).

As an example, the area of the pattern of the orthographic projection on the substrate of the red-color luminescent sublayer R-EM within the edge region AA-B (the second pixel units P2) is equal to the area of the pattern of the orthographic projection on the substrate of the red-color luminescent sublayer R-EML within the center region AA-M (the first pixel units P1), the area of the pattern of the orthographic projection on the substrate of the green-color luminescent sublayer G-EM within the edge region AA-B (the second pixel units P2) is equal to the area of the pattern of the orthographic projection on the substrate of the green-color luminescent sublayer G-EML within the center region AA-M (the first pixel units P1), and the area of the pattern of the orthographic projection on the substrate of the blue-color luminescent sublayer B-EM within the edge region AA-B (the second pixel units P2) is equal to the area of the pattern of the orthographic projection on the substrate of the blue-color luminescent sublayer B-EML within the center region AA-M (the first pixel units P1).

In the embodiments of the present application, for the sub-pixels of the same color, by configuring that the area of the pattern of the orthographic projection on the substrate of each of the luminescent sublayers (for example, R-EML, G-EML and B-EML) within the edge region AA-B (the second pixel units P2) is equal to the area of the pattern of the orthographic projection on the substrate of each of the luminescent sublayers (for example, R-EML, G-EML and B-EML) within the center region AA-M (the first pixel units P1), that can significantly reduce the difficulty in the fabricating process of the mask for the luminescent sublayers (FMM Mask), to reduce the cost.

The area of the pattern of the orthographic projection on the substrate of each of the functional sublayers CL-P2 within the edge region AA-B (the second pixel units P2) is greater than the area of the pattern of the orthographic projection on the substrate of each of the functional sublayers CL-P1 within the center region AA-M (the first pixel units P1). The functional sublayers CL may include at least one of a hole injection sublayer, a hole transporting sublayer, an electron injection sublayer, an electron transporting sublayer and a charge transporting sublayer.

As an example, the area of the pattern of the orthographic projection on the substrate of the hole transporting sublayer (HTL) within the edge region AA-B (the second pixel units P2) is greater than the area of the pattern of the orthographic projection on the substrate of the hole transporting sublayer within the center region AA-M (the first pixel units P1).

As an example, the area of the pattern of the orthographic projection on the substrate of the electron transporting sublayer (ETL) within the edge region AA-B (the second pixel units P2) is greater than the area of the pattern of the orthographic projection on the substrate of the hole transporting sublayer within the center region AA-M (the first pixel units P1).

In the displaying base board according to the embodiments of the present application, by configuring that the area of the pattern of the orthographic projection on the substrate of each of the functional sublayers CL-P2 within the edge region AA-B (the second pixel units P2) is greater than the area of the pattern of the orthographic projection on the substrate of each of the functional sublayers CL-PI within the center region AA-M (the first pixel units P1), the aperture ratio of the second pixel units P2 within the edge region AA-B can be significantly increased, thereby improving the effect of the compensation for the light rays at the splicing-seam position by the second pixel units P2 within the edge region. That does not only improve the effect of displaying of the spliced displaying device, bu also prolongs the life of the second pixel units P2 within the edge region AA-B, thereby improving the quality of the product.

In the displaying base board according to an embodiment of the present application, within the center region AA-M, for the same one sub-pixel, as shown in FIG. 5, for example, in a sub-pixel of the first pixel units P1, the orthographic projection of the luminescent sublayer (E-EML, G-EML or B-EML) on the substrate and the orthographic projection of the functional sublayer CL on the substrate partially overlap.

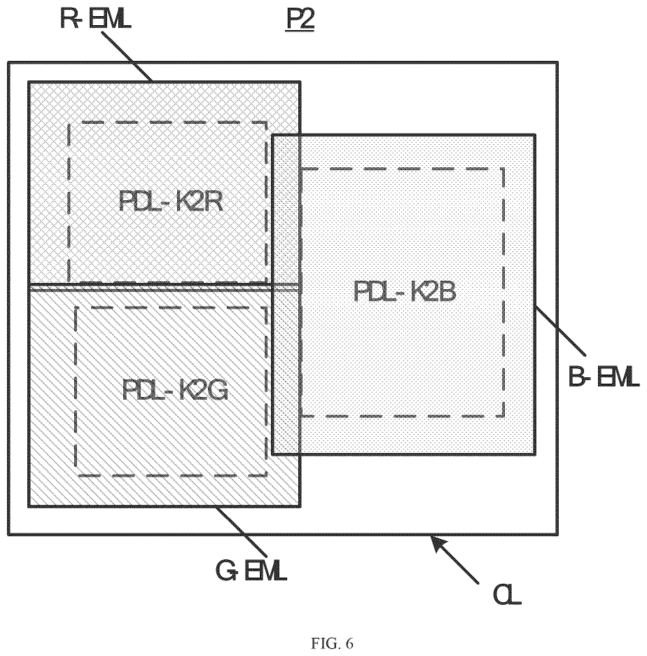

Within the edge region, for the same one sub-pixel, as shown in FIG. 6, for example, in a sub-pixel of the second pixel units P2, the orthographic projection of the luminescent sublayer (E-EML, G-EML or B-EML) on the substrate is located within the orthographic projection of the functional sublayer CL on the substrate.

As an example, as shown in FIG. 6, in the sub-pixels of the second pixel unit P2, the outer contours of the orthographic projections of the luminescent sublayers (E-EML, G-EML or B-EML) on the substrate are located within the outer contour of the orthographic projection of the functional sublayer CL on the substrate.

In the embodiments of the present application, by configuring that the sizes and the shapes of the luminescent sublayers of the sub-pixels of the same color within the center region AA-M and the edge region AA-B are the same, it is configured that the size of the functional sublayers CL within the edge region AA-B is increased, and the size of the second openings K2 within the edge region AA-B is increased. That can significantly increase the aperture ratio of the pixel units within the edge region AA-B, and if the aperture ratio is higher, the areas of the light emitting regions are higher, so as to increase the total brightness of the light rays emitted by the second pixel units P2 within the edge region AA-B, thereby improving the effect of the compensation for the light rays at the splicing-seam position by the second pixel units P2 within the edge region AA-B. That does not only improve the effect of displaying of the spliced displaying device, but also prolongs the life of the second pixel units P2 within the edge region AA-B, thereby improving the quality of the product.

In the displaying base board according to an embodiment of the present application, as shown in FIG. 4, within the center region AA-M, the functional sublayers CL of the sub-pixels in the same one first pixel unit P1 are integral, and the functional sublayers CL in two neighboring first pixel units P1 are disconnected. Within the edge region AA-B, the functional sublayers CL of the sub-pixels in the same one second pixel unit P2 are integral, and the functional sublayers CL in at least two second pixel units P2 are integral.

In the embodiments of the present application, because it is configured that the size of the openings (the second openings K2) of the pixel defining layer of the second pixel units P2 within the edge region AA-B is greater than the size of the openings (the first openings K1) of the pixel defining layer of the first pixel units P1 within the center region, by configuring that the functional sublayers CL in at least two second pixel units P2 are integral, not only it can be ensured that the aperture ratio of the second pixel units P2 within the edge region is increased, but also the difficulty and the risk in the fabricating process of the second pixel units P2 within the edge region are reduced to a large extent, thereby increasing the yield of the fabrication of the displaying base board, and improving the product quality.

In the displaying base board according to an embodiment of the present application, as shown in FIG. 4, if the functional sublayers CL in at least two second pixel units P are integral, the orthographic projection on the substrate of the functional sublayers CL that are integral covers the region between two neighboring second pixel units P2. The orthographic projections of the connecting electrodes LJ on the substrate and the orthographic projection on the substrate of the functional sublayers CL that are integral do not overlap with each other.

In the displaying base board according to an embodiment of the present application, as shown in FIG. 8, the displaying base board further comprises a cathode layer CA, the cathode layer CA comprises a plurality of cathodes, the plurality of cathodes are integral, the cathode layer CA covers the pixel defining layer PDL, and the cathode layer CA contacts and is conducted with the connecting electrodes LJ.

In the embodiments of the present application, by configuring that the orthographic projections of the connecting electrodes LJ on the substrate and the orthographic projection on the substrate of the functional sublayers CL that are integral do not overlap with each other, referring to FIG. 8, when the connecting electrodes LJ and the cathode layer CA are conducted, the functional sublayers CL of the sub-pixels are not interfered, thereby ensuring the normal light emission of the sub-pixels.

In the embodiments of the present application, by providing the connecting electrodes LJ within the displaying region, the connecting electrodes LJ are conducted with the cathodes and the anodes, thereby forming the closed loops of the pixel driving circuits. As compared with the related art, in which the connecting electrodes LJ are provided within the peripheral region (for example, annular connecting electrodes, also referred to as cathode rings), that can significantly reduce the size of the border frame, thereby further reducing the practical size of the splicing seam, to improve the effect of displaying.

In the displaying base board according to an embodiment of the present application, the spacings between the light emitting regions F of two neighboring first pixel units P1 are equal, and the spacings between the light emitting regions F of two neighboring second pixel units P2 are equal.

In the displaying base board according to an embodiment of the present application, all of the spacings between the light emitting regions F of any two neighboring pixel units (including the first pixel units P1 and the second pixel units P2) are equal.

In the embodiments of the present application, by configuring that all of the spacings between the light emitting regions F of any two neighboring pixel units (including the first pixel units P1 and the second pixel units P2) are equal, the light emitting regions F of the pixel units are evenly distributed, thereby improving the brightness uniformity of the displaying base board.

In the displaying base board according to an embodiment of the present application, N rings of the second pixel units P2 are arranged along the lateral sides of the displaying base board. The pattern of the orthographic projection of the displaying region on the substrate comprises a first corner, a second corner, a third corner and a fourth corner, the functional sublayers CL of N*N second pixel units P2 that are located at the first corner are integral, the functional sublayers CL of N*N second pixel units P2 that are located at the second corner are integral, the functional sublayers CL of N*N second pixel units P2 that are located at the third corner are integral, and the functional sublayers CL of N*N second pixel units P2 that are located at the fourth corner are integral. N is greater than or equal to 2.

As shown in FIG. 4, 2 rings of the second pixel units P2 are arranged along the lateral sides of the displaying base board. The pattern of the orthographic projection of the displaying region on the substrate comprises a first corner, a second corner, a third corner and a fourth corner, the functional sublayers CL of 2*2 second pixel units P2 that are located at the first corner are integral, the functional sublayers CL of 2*2 second pixel units P2 that are located at the second corner are integral, the functional sublayers CL of 2*2 second pixel units P2 that are located at the third corner are integral, and the functional sublayers CL of 2*2 second pixel units P2 that are located at the fourth corner are integral.

In the embodiments of the present application, because it is configured that the size of the openings (the second openings K2) of the pixel defining layer of the second pixel units P2 within the edge region AA-B is greater than the size of the openings (the first openings K1) of the pixel defining layer of the first pixel units P1 within the center region, by the integral configuration of the functional sublayers CL in the plurality of second pixel units P2 at the corners, not only it can be ensured that the aperture ratio of the second pixel units P2 within the edge region is increased, but also the difficulty and the risk in the fabricating process of the second pixel units P2 within the edge region are reduced to a large extent, thereby increasing the yield of the fabrication of the displaying base board, and improving the product quality.

It should be noted that, besides the components described above, the displaying base board may further comprise other components. For example, it comprises a planarizing layer PLN and a driving circuit, and further comprises a peripheral region surrounding the displaying region AA, the peripheral region comprises a bonding sub-region BD, and the bonding sub-region BD contains bonding terminals and so on. Merely the components that are relevant to the inventiveness are described herein, and the other components comprised by the displaying base board may refer to the description in the related art.

An embodiment of the present application provides a display panel, wherein the display panel comprises the displaying base board stated above.

In the display panel according to the embodiments of the present application, by, in the displaying base board, configuring that the area of the light emitting region F of each of the second pixel units P2 within the edge region AA-B is greater than the area of the light emitting region of each of the first pixel units P1 within the center region AA-M, when the display panel formed by the displaying base board is controlled to display, it may be configured that the brightnesses of all of the pixel units are equal (for example, by configuring that the voltages of the anodes of all of the pixel units are equal). Because the area of the light emitting region F of each of the second pixel units P2 within the edge region AA-B is greater than the area of the light emitting region F of each of the first pixel units P1 within the center region AA-M, the total intensity of the light rays of the second pixel units P2 is greater than the total intensity of the light rays of the first pixel units P1. Therefore, when the spliced displaying device is formed, the second pixel units P2 within the edge region AA-B, after compensating the brightness at the splicing-seam position, can maintain the brightness of the positions themselves. That does not only ameliorate the problem of the splitting sensation of the frame at the splicing-seam position and ensure the brightness uniformity of the spliced displaying device, but also can prolong the service life of the spliced displaying device and improve the product quality.

An embodiment of the present application provides a spliced displaying device, wherein the spliced displaying device comprises at least two display panels stated above.

In the spliced displaying device according to the embodiments of the present application, by, in the displaying base board, configuring that the area of the light emitting region F of each of the second pixel units P2 within the edge region AA-B is greater than the area of the light emitting region of each of the first pixel units P1 within the center region AA-M, when the display panel formed by the displaying base board is controlled to display, it may be configured that the brightnesses of all of the pixel units are equal (for example, by configuring that the voltages of the anodes of all of the pixel units are equal). Because the area of the light emitting region F of each of the second pixel units P2 within the edge region AA-B is greater than the area of the light emitting region F of each of the first pixel units P1 within the center region AA-M, the total intensity of the light rays of the second pixel units P2 is greater than the total intensity of the light rays of the first pixel units P1. Therefore, when the spliced displaying device is formed, the second pixel units P2 within the edge region AA-B, after compensating the brightness at the splicing-seam position, can maintain the brightness of the positions themselves. That does not only ameliorate the problem of the splitting sensation of the frame at the splicing-seam position and ensure the brightness uniformity of the spliced displaying device, but also can prolong the service life of the spliced displaying device and improve the product quality.

The above are merely particular embodiments of the present application, and the protection scope of the present application is not limited thereto. All of the variations or substitutions that a person skilled in the art can easily envisage within the technical scope disclosed by the present application should fall within the protection scope of the present application. Therefore, the protection scope of the present application should be subject to the protection scope of the claims.

1. A displaying base board, wherein the displaying base board comprises a displaying region;
the displaying region comprises a center region and an edge region surrounding the center region, the center region contains a plurality of first pixel units arranged in an array, the edge region contains a plurality of second pixel units, and at least one row of the second pixel units are arranged along a lateral side of the displaying base board;
an area of a light emitting region of each of the second pixel units is greater than an area of a light emitting region of each of the first pixel units;
the displaying base board comprises a substrate and a first electrically conducting layer located on the substrate, and the first electrically conducting layer comprises a plurality of anodes; and
each of the pixel units comprises a plurality of sub-pixels, and for the instances of the sub-pixels of a same color, an area of an orthographic projection on the substrate of each of the anodes of the sub-pixels located within the edge region is greater than an area of an orthographic projection on the substrate of each of the anodes of the sub-pixels located within the center region.

2. The displaying base board according to claim 1, wherein the displaying base board comprises a first lateral side, a second lateral side, a third lateral side and a fourth lateral side that are sequentially connected, and the at least one row of the second pixel units are arranged along at least one of the first lateral side, the second lateral side, the third lateral side and the fourth lateral side.

3. The displaying base board according to claim 1, wherein the displaying base board further comprises a pixel defining layer, the pixel defining layer comprises a plurality of first openings and a plurality of second openings, the first openings are located within the center region, and the second openings are located within the edge region;
a region encircled by an orthographic projection of an outer contour of each of the first openings on the substrate overlaps with the orthographic projection on the substrate of the anode of the each of the sub-pixels located within the center region, and a region encircled by an orthographic projection of an outer contour of each of the second openings on the substrate overlaps with the orthographic projection on the substrate of the anode of the each of the sub-pixels located within the edge region; and
for the instances of the sub-pixels of a same color, an area of a pattern of the orthographic projection of the outer contour of each of the first openings on the substrate is less than an area of a pattern of the orthographic projection of the outer contour of each of the second openings on the substrate.

4. The displaying base board according to claim 3, wherein the first electrically conducting layer further comprises a plurality of connecting electrodes, orthographic projections of the connecting electrodes on the substrate and orthographic projections of the pixel units on the substrate do not overlap with each other, and the connecting electrodes are electrically connected to the anodes;
the pixel defining layer comprises a plurality of third openings, and regions encircled by orthographic projections of outer contours of the third openings on the substrate overlap with the orthographic projections of the connecting electrodes on the substrate;
a quantity of the third openings is equal to a quantity of the connecting electrodes; and
the connecting electrodes are located at least within the center region.

5. The displaying base board according to claim 4, wherein some of the connecting electrodes are located within the center region, and some of the connecting electrodes are located within the edge region; and
a distribution density of the connecting electrodes located within the center region is greater than a distribution density of the connecting electrodes located within the edge region.

6. The displaying base board according to claim 4, wherein some of the connecting electrodes are located within the center region, and some of the connecting electrodes are located within the edge region; and
a quantity of the connecting electrodes located within the center region is greater than a quantity of the connecting electrodes located within the edge region.

7. The displaying base board according to claim 5, wherein each of the sub-pixels comprises a luminescent functional layer, and the luminescent functional layer is located on one side of the anodes that is farther from the substrate; and
for the instances of the sub-pixels of a same color, an area of a pattern of an orthographic projection on the substrate of each of the luminescent functional layers within the edge region is greater than an area of a pattern of an orthographic projection on the substrate of each of the luminescent functional layers within the center region.

8. The displaying base board according to claim 7, wherein each of the luminescent functional layers comprises a luminescent sublayer and a functional sublayer; and
for the instances of the sub-pixels of a same color, an area of a pattern of an orthographic projection on the substrate of each of the luminescent sublayers within the edge region is equal to an area of a pattern of an orthographic projection on the substrate of each of the luminescent sublayers within the center region, and an area of a pattern of an orthographic projection on the substrate of each of the functional sublayers within the edge region is greater than an area of a pattern of an orthographic projection on the substrate of each of the functional sublayers within the center region.

9. The displaying base board according to claim 8, wherein
within the center region, for a same one instance of the sub-pixels, the orthographic projection of the luminescent sublayer on the substrate and the orthographic projection of the functional sublayer on the substrate partially overlap; and
within the edge region, for a same one instance of the sub-pixels, the orthographic projection of the luminescent sublayer on the substrate is located within the orthographic projection of the functional sublayer on the substrate.

10. The displaying base board according to claim 8, wherein
within the center region, the functional sublayers of the sub-pixels in a same one instance of the first pixel units are integral, and the functional sublayers in two neighboring instances of the first pixel units are disconnected; and
within the edge region, the functional sublayers of the sub-pixels in a same one instance of the second pixel units are integral, and the functional sublayers in at least two instances of the second pixel units are integral.

11. The displaying base board according to claim 10, wherein if the functional sublayers in at least two instances of the second pixel units are integral, an orthographic projection on the substrate of the functional sublayers that are integral covers a region between two neighboring instances of the second pixel units; and
the orthographic projections of the connecting electrodes on the substrate and the orthographic projection on the substrate of the functional sublayers that are integral do not overlap with each other.

12. The displaying base board according to claim 4, wherein the displaying base board further comprises a cathode layer, the cathode layer comprises a plurality of cathodes, the plurality of cathodes are integral, the cathode layer covers the pixel defining layer, and the cathode layer contacts and is conducted with the connecting electrodes.

13. The displaying base board according to claim 1, wherein spacings between the light emitting regions of two neighboring instances of the first pixel units are equal, and spacings between the light emitting regions of two neighboring instances of the second pixel units are equal.

14. The displaying base board according to claim 1, wherein all of spacings between the light emitting regions of any two neighboring instances of the pixel units are equal.

15. The displaying base board according to claim 10, wherein N rings of the second pixel units are arranged along the lateral sides of the displaying base board; and
a pattern of an orthographic projection of the displaying region on the substrate comprises a first corner, a second corner, a third corner and a fourth corner, the functional sublayers of N*N instances of the second pixel units that are located at the first corner are integral, the functional sublayers of N*N instances of the second pixel units that are located at the second corner are integral, the functional sublayers of N*N instances of the second pixel units that are located at the third corner are integral, and the functional sublayers of N*N instances of the second pixel units that are located at the fourth corner are integral;
wherein N is greater than or equal to 2.

16. The displaying base board according to claim 8, wherein the functional sublayers include at least one of a hole injection sublayer, a hole transporting sublayer, an electron injection sublayer, an electron transporting sublayer and a charge transporting sublayer.

17. A display panel, wherein the display panel comprises the displaying base board according to claim 1.

18. A spliced displaying device, wherein the spliced displaying device comprises at least two instances of the display panel according to claim 17.

19. The displaying base board according to claim 6, wherein each of the sub-pixels comprises a luminescent functional layer, and the luminescent functional layer is located on one side of the anodes that is farther from the substrate; and
for the instances of the sub-pixels of a same color, an area of a pattern of an orthographic projection on the substrate of each of the luminescent functional layers within the edge region is greater than an area of a pattern of an orthographic projection on the substrate of each of the luminescent functional layers within the center region.
